(19) United States
(12) Patent Application Publication
(10) Pub. No.: US 2024/0096773 A1
(43) Pub. Date: Mar. 21, 2024

(54) SEMICONDUCTOR PACKAGE

(71) Applicant: Samsung Electronics Co., Ltd., Suwon-si (KR)

(72) Inventors: Dongkyu Kim, Suwon-si (KR); Kyounglim Suk, Suwon-si (KR); Yeonho Jang, Suwon-si (KR); Hyeonjeong Hwang, Suwon-si (KR)

(21) Appl. No.: 18/319,135

(22) Filed: May 17, 2023

(30) Foreign Application Priority Data
Sep. 16, 2022 (KR) 10-2022-0116884

(51) Int. Cl. H01L 23/498; H01L 23/00; H01L 23/31; H01L 23/538

(52) U.S. Cl. CPC H01L 23/49816; H01L 23/3128; H01L 23/49838; H01L 23/5389; H01L 24/05; H01L 24/13; H01L 24/16; H01L 2224/0401; H01L 2224/04105; H01L 2224/05093; H01L 2224/13008; H01L 2224/13009; H01L 2224/13022; H01L 2224/16227; H01L 2924/1434

(57) ABSTRACT

A semiconductor package includes a redistribution structure in which at least one redistribution layer and at least one insulating layer are alternately stacked; a semiconductor chip electrically connected to the at least one redistribution layer; and bumps on the redistribution structure, wherein the redistribution structure includes vias extending from the at least one redistribution layer in a vertical stacking direction of the redistribution structure; and under bump metallurgy (UBM) structures electrically connected between the vias and the bumps and configured to face the bumps in the vertical stacking direction of the redistribution structure, wherein each of the UBM structures includes a first UBM layer including a first metal material or an alloy of the first metal material; and a second UBM layer between one of the bumps and the first UBM layer and including a second metal material.

### CROSS-REFERENCE TO RELATED APPLICATION(S)

This application claims benefit of priority to Korean Patent Application No. 10-2022-0116884 filed on Sep. 16, 2022 in the Korean Intellectual Property Office, the disclosure of which is incorporated herein by reference in its entirety.

### BACKGROUND

Example embodiments of the present disclosure relate to a semiconductor package.

Generally, a semiconductor chip may be implemented as a semiconductor package such as a wafer level package (WLP) or a panel level package (PLP), and a semiconductor package may be used as an electronic component of a device.

A semiconductor package may include a redistribution layer for electrically connecting a semiconductor chip to a device or a printed circuit board. The redistribution layer (RDL) may have a structure in which redistribution layers, implemented to be finer than wirings of wiring layers of a general printed circuit board, are extended horizontally.

The redistribution layer may be electrically connected to bumps to extend an electrical connection path vertically, and under bump metallurgy (UBM) may improve electrical connection efficiency between a redistribution layer and a bump.

### SUMMARY

An example embodiment of the present disclosure is to provide a semiconductor package having improved reliability (or reliability for unit cost/size) of under bump metallurgy (UBM) structures.

According to an example embodiment of the present disclosure, a semiconductor package includes a redistribution structure in which at least one redistribution layer and at least one insulating layer are alternately stacked; a semiconductor chip electrically connected to the at least one redistribution layer; and bumps on the redistribution structure, wherein the redistribution structure includes vias extending from the at least one redistribution layer in a vertical stacking direction of the redistribution structure; and UBM structures electrically connected between the vias and the bumps and configured to face the bumps in a vertical stacking direction of the redistribution structure, wherein each of the UBM structures includes a first UBM layer including a first metal material or an alloy of the first metal material; and a second UBM layer between one of the bumps and the first UBM layer and including a second metal material different from the first metal material or an alloy of the second metal material, and wherein an area of a surface of the second UBM layer facing the first UBM layer is greater than an area of a surface of the first UBM layer facing the second UBM layer.

According to an example embodiment of the present disclosure, a semiconductor package includes a redistribution structure in which at least one redistribution layer and at least one insulating layer are alternately stacked; a semiconductor chip electrically connected to the at least one redistribution layer; and bumps on the redistribution structure, wherein the redistribution structure includes vias extending from the at least one redistribution layer in a vertical stacking direction of the redistribution structure; and UBM structures electrically connected between the vias and the bumps and configured to face the bumps in the vertical stacking direction of the redistribution structure, wherein each of the UBM structures includes a first UBM layer including a first metal material or an alloy of the first metal material; and a second UBM layer between one of the bumps and the first UBM layer and including a second metal material different from the first metal material or an alloy of the second metal material, and wherein a side surface of the first UBM layer has a curvature or taper that is greater than a curvature or taper of a side surface of the second UBM layer.

According to an example embodiment of the present disclosure, a semiconductor package includes a redistribution structure in which at least one redistribution layer and at least one insulating layer are alternately stacked; a semiconductor chip electrically connected to the at least one redistribution layer; and bumps on the redistribution structure, wherein the redistribution structure includes vias extending from the at least one redistribution layer in a vertical stacking direction of the redistribution structure; and UBM structures electrically connected between the vias and the bumps and configured to face the bumps in the vertical stacking direction of the redistribution structure, wherein each of the UBM structures includes a second UBM layer embedded in the at least one insulating layer and including a second metal material or an alloy of the second metal material; and a first UBM layer electrically connected between one of the vias and the second UBM layer and including a first metal material different from the second metal material or an alloy of the first metal material, and wherein the at least one insulating layer is in contact with a portion of a surface of the second UBM layer facing the first UBM layer and is in contact with a side surface of the second UBM layer.

### BRIEF DESCRIPTION OF DRAWINGS

The above and other aspects, features, and advantages of the present disclosure will be more clearly understood from the following detailed description, taken in combination with the accompanying drawings, in which:

FIGS. 1A and 1B are cross-sectional diagrams illustrating a semiconductor package according to an example embodiment of the present disclosure;

FIGS. 1C and 1D are plan diagrams illustrating a semiconductor package according to an example embodiment of the present disclosure;

FIGS. 2A and 2B are cross-sectional diagrams illustrating a redistribution structure of a semiconductor package and various structures of a semiconductor chip according to an example embodiment of the present disclosure;

FIG. 3A is a cross-sectional diagram illustrating a structure in which a redistribution structure and UBM structures of a semiconductor package are above a semiconductor chip according to an example embodiment of the present disclosure;

FIG. 3B is a cross-sectional diagram illustrating a surface treatment layer of UBM structures of a semiconductor package according to an example embodiment of the present disclosure;

FIG. 3C is a cross-sectional diagram illustrating a detailed shape of a side surface of a first UBM layer of a semiconductor package according to an example embodiment of the present disclosure;

FIGS. 4A to 4E are cross-sectional diagrams illustrating a method of manufacturing which may implement a difference in area between surfaces of first and second UBM layers facing each other of a semiconductor package according to an example embodiment of the present disclosure;

FIGS. 5A to 5F are cross-sectional diagrams illustrating a method of forming a semiconductor chip of a semiconductor package and a surrounding structure thereof according to an example embodiment of the present disclosure;

FIGS. 6A to 6D are cross-sectional diagrams illustrating a method of arranging bumps of a semiconductor package on UBM structures according to an example embodiment of the present disclosure; and

FIGS. 7A and 7B are cross-sectional diagrams illustrating an additional process of manufacturing a semiconductor package according to an example embodiment of the present disclosure.

### DETAILED DESCRIPTION

Hereinafter, embodiments of the present disclosure will be described as follows with reference to the accompanying drawings.

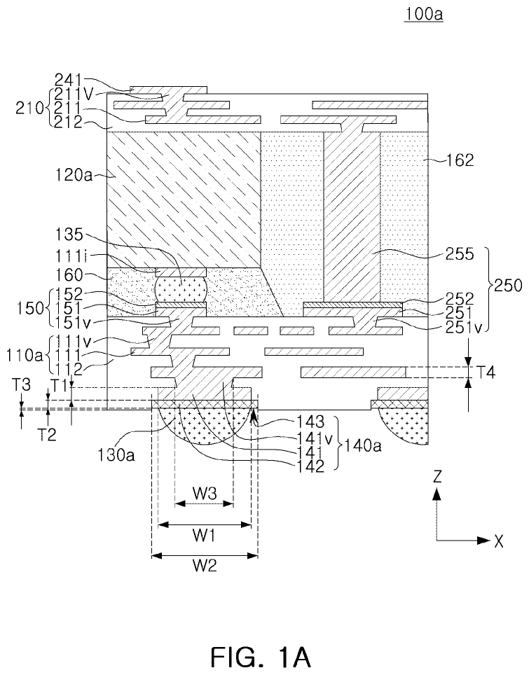

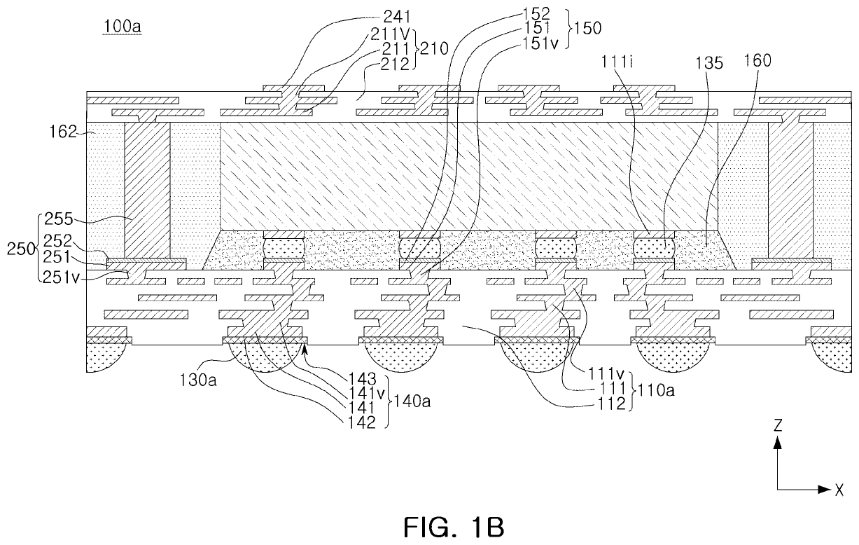

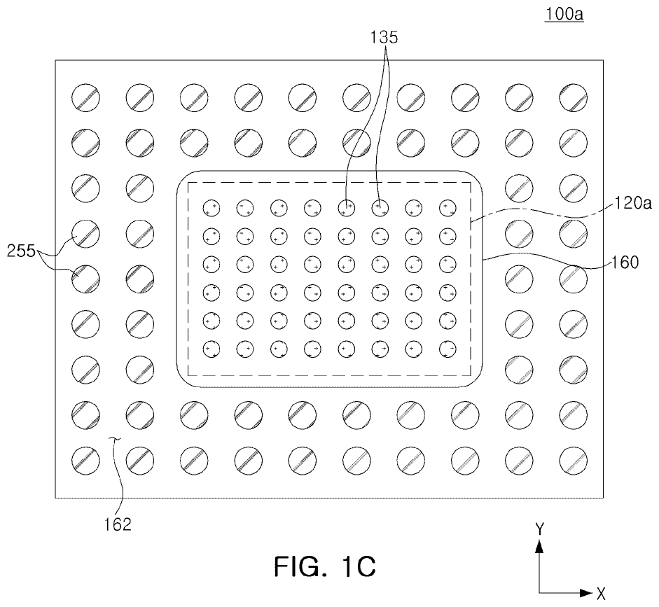

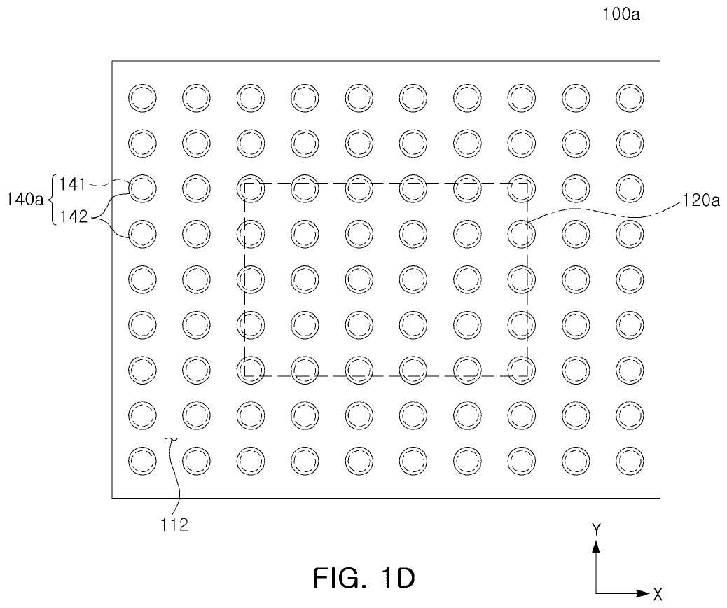

FIGS. 1A and 1B are cross-sectional diagrams illustrating a semiconductor package according to an example embodiment.

Referring to FIGS. 1A and 1B, a semiconductor package 100a in an example embodiment may include a redistribution structure 110a, a semiconductor chip 120a, bumps 130a, and UBM structures 140a, and each of the UBM structures 140a may include a first UBM layer 141 and a second UBM layer 142.

FIG. 1A illustrates a fan-out structure in which a portion of the redistribution structure 110a vertically overlaps the semiconductor chip 120a and the other portion of the redistribution structure 110a does not vertically overlap the semiconductor chip 120a, but an example embodiment thereof is not limited thereto. The fan-out structure may be extended to a package on package (POP) structure or may be a system in package (SIP) structure.

The redistribution structure 110a may have a structure in which at least one redistribution layer 111 and at least one insulating layer 112 are alternately stacked. The redistribution structure 110a may further include vias 111v and 141v extending from at least one redistribution layer 111 in a vertical stacking direction (e.g., Z-direction) of the redistribution structure 110a. The vias 111v and 141v may penetrate through at least one insulating layer 112.

At least one insulating layer 112 may include an insulating material, and may include, for example, a thermosetting resin such as epoxy resin or a thermoplastic resin such as polyimide. For example, at least one insulating layer 112 may include a photosensitive insulating material such as photoimageable dielectric (PID) resin. Alternatively, at least one insulating layer 112 may include a resin mixed with an inorganic filler, for example, Ajinomoto build-up film (ABF). Alternatively, at least one insulating layer 112 may include prepreg, flame retardant (FR-4), or bismaleimide triazine (BT). At least one insulating layer 112 may include the same material or different materials, and a boundary between the layers may not be distinct depending on materials included in each layer and processes.

The redistribution layers 111 and the vias 111v and 141v may form an electrical path. The redistribution layers 111 may be in a line shape on the x-y plane, and the vias 111v and 141v may have a cylindrical shape having an inclined side surface of which a width may decrease toward the lower or upper portions. The vias 111v and 141v may have a filled via structure completely filled with a conductive material, but an example embodiment thereof is not limited thereto. For example, the vias 111v and 141v may have a conformal via shape in which a metal material is formed along an inner wall of the via hole.

The redistribution layers 111 and the vias 111v and 141v may include a conductive material, such as, for example, copper (Cu), aluminum (Al), silver (Ag), tin (Sn), gold (Au), nickel (Ni), lead (Pb), titanium (Ti), or alloys thereof.

The semiconductor chip 120a may be electrically connected to at least one redistribution layer 111. The semiconductor chip 120a may be on the redistribution structure 110a. For example, the semiconductor chip 120a may include a body portion including a semiconductor material such as silicon (Si), germanium (Ge), or gallium arsenide (GaAs), and a device layer or an active layer below the body portion and including an integrated circuit (IC). The semiconductor chip 120a may include a logic semiconductor chip and/or a memory semiconductor chip. The logic semiconductor chip may be implemented as a microprocessor, for example, a central processing unit (CPU), a graphic processing unit (GPU), a field programmable gate array (FPGA), an application processor (AP), a digital signal processor, a cryptographic processor, a controller, or an application specific integrated circuit (ASIC). The memory semiconductor chip may be implemented as a volatile memory such as a dynamic random access memory (DRAM) or static random access memory (SRAM) or a non-volatile memory such as flash memory.

The semiconductor chip 120a may be mounted on the upper surface of the redistribution structure 110a by a flip-chip bonding method, and may include connection pads 111i on the lower surface of the semiconductor chip 120a. For example, the connection pads 111i may include a conductive material such as tungsten (W), aluminum (Al), or copper (Cu), and may be a pad of a bare chip, for example, aluminum (Al) pad, or in example embodiments, the connection pad 111i may be a pad of a packaged chip, for example, a copper (Cu) pad.

The bumps 130a may be electrically connected to at least one redistribution layer 111 and may be on one surface (e.g., a lower surface) of the redistribution structure 110a. For example, the bumps 130a may have a ball or column shape, and may include solder including tin (Sn) or an alloy (Sn—Ag—Cu) including tin (Sn). Since the bumps 130a may have a relatively low melting point compared to other metal materials, the bumps 130a may be connected and fixed to the UBM structures 140a by a thermal compression bonding (TCB) process or a reflow process.

The UBM structures 140a may be electrically connected between the vias 111v and 141v and the bumps 130a, and may be configured to face the bumps 130a in a vertical stacking direction (e.g., Z-direction) of the redistribution structure 110a. For example, the UBM structures 140a may provide a sufficiently wide bottom surface such that a portion of the material of the bumps 130a does not leak sideways when the bumps 130a are formed, and the bumps 130a are UBM may be in contact with the wide lower surfaces of the structures 140a. Accordingly, the UBM structures 140a may be advantageous in reducing contact resistance between the bumps 130a and the at least one redistribution layer 111.

The first UBM layer 141 of each of the UBM structures 140a may include a first metal material (e.g., copper) or an alloy of the first metal material. For example, the first metal material may have high conductivity and high wettability with respect to the material of the bumps 130a (e.g., a solder material), and may be copper. Accordingly, the first UBM layer 141 may increase electrical connection efficiency between the bumps 130a and the redistribution layer 111.

As conductivity and wettability of the metal material contained in the UBM structures 140a is higher, the portions of the UBM structures 140a in which the metal material (e.g., the first metal material) is disposed may interact more strongly with the bumps 130a, and may receive a stronger bonding force or attraction according to the interaction. This phenomenon may be represented as copper consumption when the metal material is copper.

The second UBM layer 142 of each of the UBM structures 140a may be between one of the bumps 130a and the first UBM layer 141, and may include a second metal material different from the first metal material (e.g., nickel) or an alloy of a second metal material. For example, the second metal material may be relatively weak in interaction with the bumps 130a being formed as compared to the first metal material or may be advantageous for bonding to the at least one insulating layer 112, and may be nickel. Nickel may have a low chemical affinity with copper, may have resistance to diffusion of copper, and may not form a structure having potential defects such as grain boundaries at a high temperature when the bumps 130a are formed, such that nickel may be most suitable for the metal material of the second UBM layer 142, but an example embodiment thereof is not limited thereto.

Property of maintaining a shape of the bumps 130a when the bumps 130a of the second UBM layer 142 are formed may be higher than that of the first UBM layer 141, and the second UBM layer 142 may be in a position for preventing interaction between the first UBM layer 141 and the bumps 130a, such that the UBM structures 140a may maintain shapes thereof when the bumps 130a are formed.

Also, an area of the surface (e.g., upper surface) of the second UBM layer 142 facing the first UBM layer 141 may be larger than the area of the surface (e.g., the lower surface) of the first UBM layer 141 facing the second UBM layer 142. Accordingly, since the second UBM layer 142 may prevent an interfacial surface between the first UBM layer 141 and the at least one insulating layer 112 from being exposed to the lower side of the second UBM layer 142, the UBM structure 140a may more efficiently maintain shapes thereof when the bumps 130a are formed, and may effectively prevent copper consumption.

For example, the area of the surface (e.g., upper surface) of the second UBM layer 142 facing the first UBM layer 141 may be calculated based on the maximum width W2 of the second UBM layer 142 and the shape (e.g., circular shape) of the surface, the area of the surface (e.g., lower surface) of the first UBM layer 141 facing the second UBM layer 142 may be calculated based on the maximum width W1 of the first UBM layer 141 and the shape (e.g., circular shape) of the surface. When the shape of the surface is circular, the maximum widths W1 and W2 may be defined as diameters. The area and maximum widths W1 and W2 may be measured by analysis using at least one of a micrometer, a transmission electron microscope (TEM), an atomic force microscope (AFM), a scanning electron microscope (SEM), a focused ion beam (FIB) optical microscope, and a surface profiler.

Alternatively, at least one insulating layer 112 may be in contact with a portion (e.g., an edge portion) of a surface (e.g., an upper surface) of the second UBM layer 142 facing the first UBM layer 141, and may be in contact with the side surface of the second UBM layer 142. Accordingly, since bonding strength between the at least one insulating layer 112 and the second UBM layer 142 may be further improved, the second UBM layer 142 may more effectively reduce or prevent interaction between the first UBM layer 141 and the bumps 130a, and may effectively reduce or prevent the copper consumption. Contact between the at least one insulating layer 112 and the second UBM layer 142 may indicate that there is no additional structure is present between the at least one insulating layer 112 and the second UBM layer 142.

Accordingly, the UBM structures 140a may maintain shapes thereof when the bumps 130a are formed and/or reduce or prevent copper consumption, and reliability of the UBM structures 140a may be further improved. The reliability may be evaluated by Board Level Reliability (BLR), contact resistance standard deviation, or electrical short prevention. The reliability may be deteriorated due to a minute gap between the UBM structures 140a and the at least one insulating layer 112 or separation from the at least one insulating layer 112 at the edge of the UBM structures 140a. However, since the UBM structures 140a may efficiently prevent the gap or the separation while properly maintaining the shapes thereof, reliability of the semiconductor package 100a may be effectively improved.

Referring to FIGS. 1A and 1B, the first UBM layer 141 may be in contact with one of the vias 141v, and the maximum width W1 of the first UBM layer may be wider than the maximum width W3 of one of the vias 141v. For example, since the first UBM layer 141 and one of the vias 141v may be formed together by a semi-additive process (SAP), the first UBM layer 141 and one of the vias 141v may be integrated with each other.

By the SAP, the thickness T1 of the first UBM layer 141 may be greater than the thickness T4 of the redistribution layer 111 and greater than the thickness T2 of the second UBM layer 142. As the thickness T1 of the first UBM layer 141 increases, the interaction between the first UBM layer 141 and the bumps 130a may increase. However, since the second UBM layer 142 may effectively prevent the interaction between the first UBM layer 141 and the bumps 130a, the UBM structures 140a may increase reliability while having a structure in contact with the vias 141v.

For example, the total thickness (T1+T2) of the first and second UBM layers 141 and 142 may be 5 μm or more and 20 μm or less, the maximum width W2 of the surface (e.g., upper surface) of the second UBM layer 142 facing the first UBM layer 141 may be greater than 50 μm and less than or equal to 300 μm, and the maximum width W1 of the surface (e.g., lower surface) of the first UBM layer 141 facing the second UBM layer 142 may be greater than or equal to 50 μm and less than 300 μm.

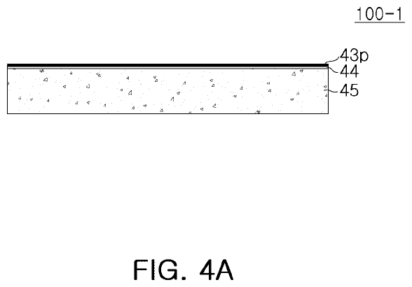

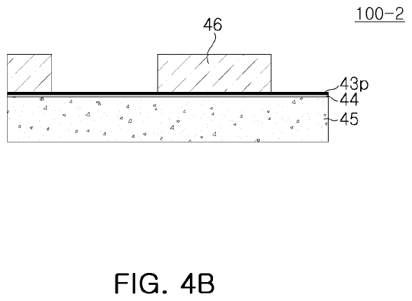

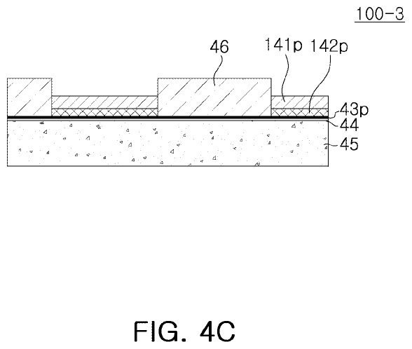

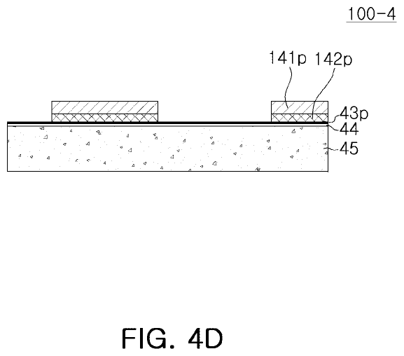

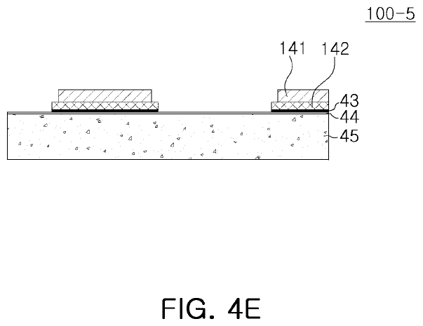

For example, the at least one insulating layer 112 may be a plurality of insulating layers, and one of the insulating layers may be on side surface of the UBM structures 140a. As illustrated, the insulating layer 112 may surround the UBM structures 140a. Due to the step difference 143 of the UBM structures 140a, the surface (e.g., the lower surface) of the second UBM layer 142 facing one of the bumps 130a may be on a level between the upper and lower surfaces of one (e.g., the lowest layer) of the insulating layer 112 on a side surface (e.g., surrounding) the UBM structures 140a. The thickness T3 of the step difference 143 may be less than the thickness (T2+T3) of one (e.g., the lowest layer) of the insulating layer 112 on a side surface of the UBM structures 140a, the step difference 143 may be a space from which the seed layer 43 in FIGS. 4E to 6B is removed.

Meanwhile, referring to FIGS. 1A and 1B, the semiconductor package 100a in an example embodiment may further include chip bumps 135, first connection structures 150, a non-conductive film layer 160, an encapsulant 162, an additional redistribution structure 210, an additional UBM structure 241, and a second electrical connection structure 250.

For example, the chip bumps 135 may be implemented in the same manner as the bumps 130a, may have a volume per unit smaller than that of the bumps 130a, and may be connected between the connection pads 111i and the first connection structures 150. As the semiconductor chip 120a is mounted on the upper surface of the redistribution structure 110a, the redistribution structure 110a may be between the semiconductor chip 120a and the bumps 130a.

For example, each of the first connection structures 150 may include a first redistribution pad 151, a first surface treatment layer 152, and a first pad via 151v, and each of the second connection structures 250 may include a second redistribution pad 251, a second surface treatment layer 252, a pad via 251v and a conductive post 255. The first and second redistribution pads 151 and 251 may be formed in the same manner as the at least one redistribution layer 111 and may have a shape (e.g., a circular plate shape) having a maximum width wider than the line width of at least one redistribution layer 111. The first and second surface treatment layers 152 and 252 may have a material different from the metal material of the first and second redistribution pads 151 and 251, and may be configured to further include contact between the first and second redistribution pads 151 and 251 and the chip bumps 135, or to protect the first and second redistribution pads 151 and 251 from the material of the chip bumps 135 permeating or overflowing. The first and second pad vias 151v and 251v may be implemented in the same manner as the vias 111v and 141v.

The non-conductive film layer 160 may surround the bumps 130a on the upper surface of the redistribution structure 110a. The non-conductive film layer 160 may be referred to as an underfill layer, may include a non-conductive polymer, and may include a non-conductive paste (NCP).

The encapsulant 162 may seal and protect the semiconductor chip 120a. The encapsulant 162 may be on (e.g., cover) the side surfaces and the upper surface of the semiconductor chip 120a, but an example embodiment thereof is not limited thereto. The encapsulant 162 may include an insulating material, for example, a thermosetting resin such as epoxy resin, a thermoplastic resin such as polyimide, prepreg including inorganic filler and/or glass fiber, ABF, FR-4, BT, epoxy molding compound (EMC), or PID.

The additional redistribution structure 210 may be formed in the same manner as the redistribution structure 110a and may be above the semiconductor chip 120a. For example, the additional redistribution structure 210 may include additional redistribution layers 211, an additional insulating layer 212, and additional vias 211V. The additional redistribution layers 211 may be formed in the same manner as at least one redistribution layer 111 and may be electrically connected to the second connection structures 250. The additional insulating layer 212 and the additional vias 211V may be formed in the same manner as the at least one insulating layer 112 and the vias 111v and 141v.

The additional UBM structure 241 may be formed in the same manner as the first UBM layer 141, may be on the upper surface of the additional redistribution structure 210, and may electrically affect the additional redistribution layers 211.

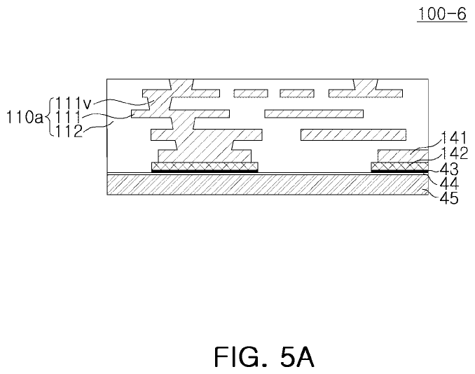

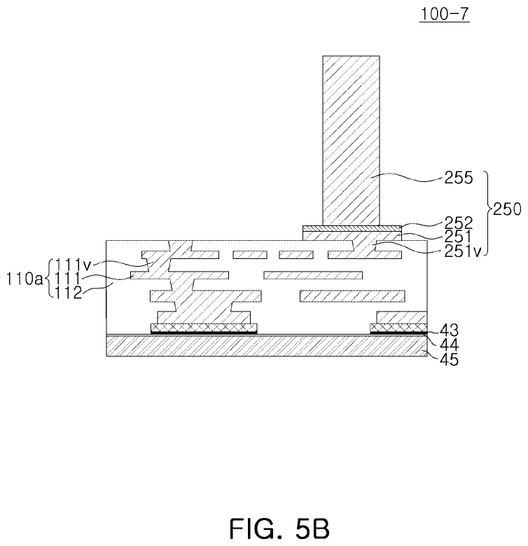

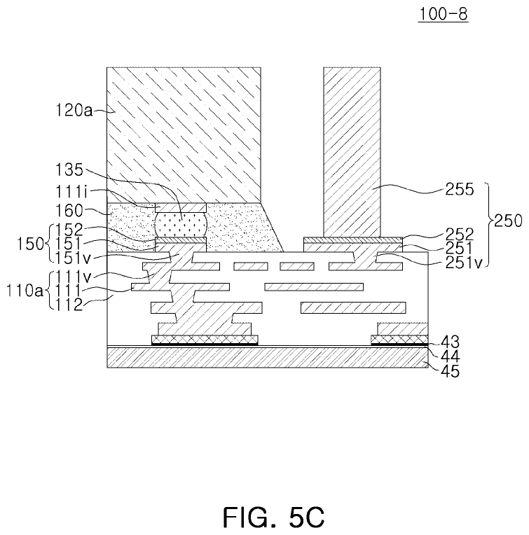

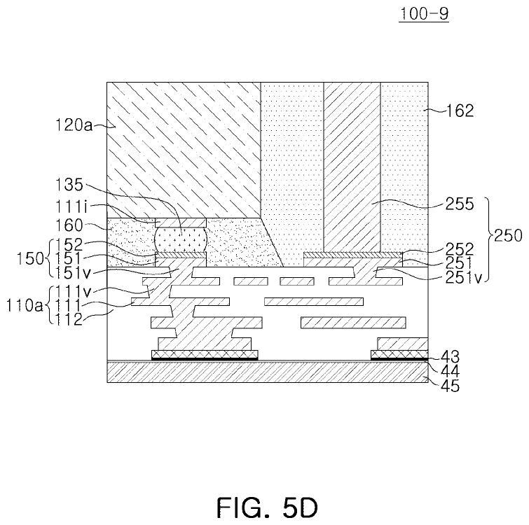

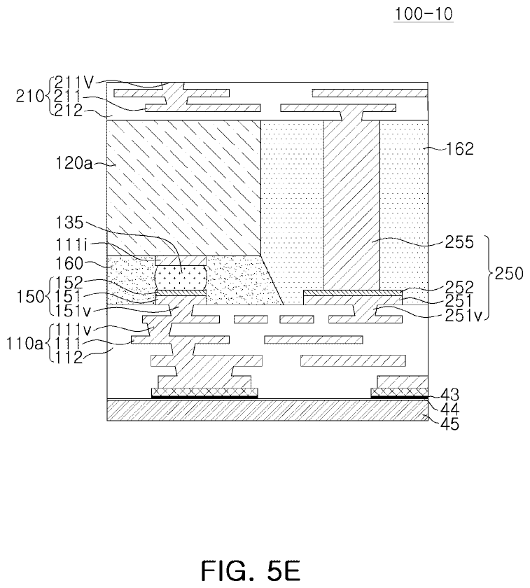

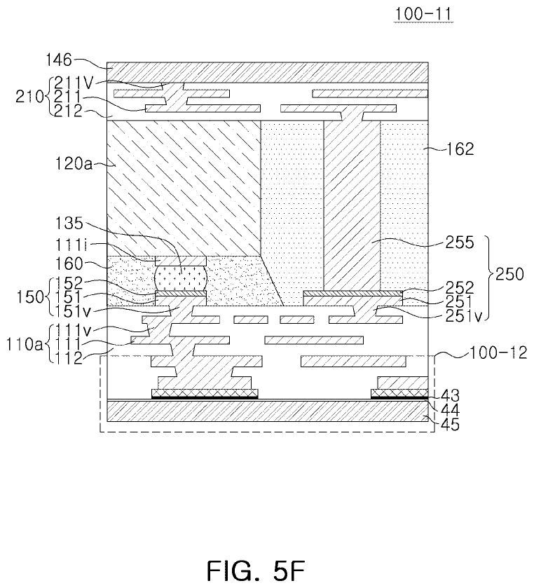

FIG. 1C is a plan diagram illustrating a semiconductor package (in FIG. 5D) from which the additional redistribution structure 210 and the additional UBM structure 241 in FIG. 1A are removed, viewed from above to below, and FIG. 1D is a plan diagram illustrating the semiconductor package in FIG. 1A viewed from below to above.

Referring to FIG. 1C, conductive posts 255 may be arranged to surround the semiconductor chip 120a, penetrate through the encapsulant 162, and may be electrically connected to at least one redistribution layer. The chip bumps 135 may be two-dimensionally arranged in positions vertically overlapping the semiconductor chip 120a.

Referring to FIG. 1D, the UBM structures 140a may be two-dimensionally arranged in positions vertically overlapping at least one insulating layer 112, and a portion of the surface of the second UBM layer 142 facing the first UBM layer 141 does not overlap the first UBM layer 141 may completely surround a region overlapping the first UBM layer 141. Stated otherwise, the second UBM layer 142 may have a surface facing the first UBM layer 141 that has an area larger than the first UBM layer 141 such that the second UBM layer includes a surface or region that does not overlap the first UBM layer 141 in a vertical direction and extends around a perimeter of the first UBM layer 141 and may completely surround a region in which the second UBM layer 142 overlaps the first UBM layer 141 in the vertical direction. Accordingly, since the exposure of the interfacial surface between the first UBM layer 141 and the at least one insulating layer 112 to the lower side of the semiconductor package may be completely prevented, reliability of the UBM structures 140a may be further improved.

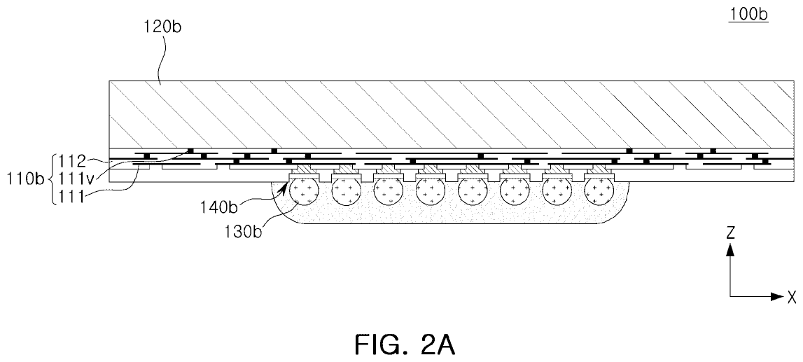

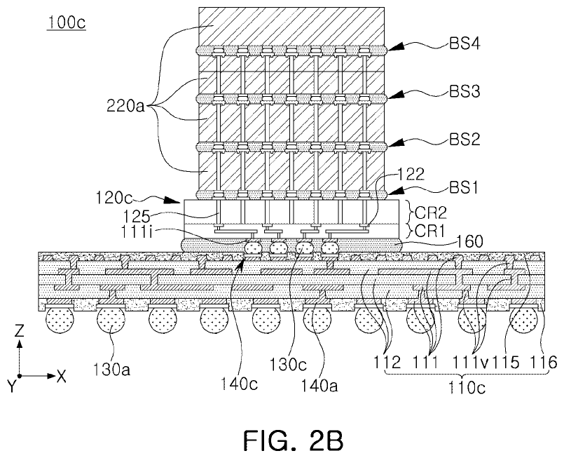

FIGS. 2A and 2B are cross-sectional diagrams illustrating a redistribution structure of a semiconductor package and various structures of a semiconductor chip according to an example embodiment.

Referring to FIG. 2A, a semiconductor package 100b according to an example embodiment may include a redistribution structure 110b, a semiconductor chip 120b, bumps 130b, and UBM structures 140b. The redistribution structure 110b, the semiconductor chip 120b, the bumps 130b, and the UBM structures 140b may be formed in the same manner as the redistribution structure 110a, the semiconductor chip 120a, the bumps 130a and the UBM structures 140a in FIGS. 1A and 1B, respectively.

In example embodiments, the semiconductor package 100b in an example embodiment may have a fan-in structure in which the redistribution structure 110a and the semiconductor chip 120a may completely overlap each other vertically, and the UBM structures 140b, which may be formed in the same manner as the UBM structures 140a in FIGS. 1A and 1B and may have a structure the same as the UBM structures 140a, may also be used in the semiconductor package 100b having a fan-in structure.

Referring to FIG. 2B, a semiconductor package 100c in an example embodiment may include a redistribution structure 110c, a semiconductor chip 120c, bumps 130c, and UBM structures 140c. The redistribution structure 110c, the semiconductor chip 120c, the bumps 130c, and the UBM structures 140c may be formed in the same manner as the redistribution structure 110a, the semiconductor chip 120a, the bumps 130a and the UBM structures 140a in FIGS. 1A and 1B, respectively.

For example, a combination structure of the semiconductor chip 120c and the semiconductor chips 220a may be a 3D integrated circuit structure as a SIP, the semiconductor chip 120c may be a logic semiconductor chip, and the semiconductor chips 220a may be memory semiconductor chips.

For example, the semiconductor chip 120c may have a lower first region CR1 and an upper second region CR2, and may further include device layers 122 and through vias 125. The first region CR1 may be a device region, and devices such as transistors and/or memory cells included in a semiconductor chip may be formed based on the second region CR2. The second region CR2 may be a substrate region, and may include, for example, a semiconductor material such as silicon (Si).

The device layers 122 may be in the first region CR1 and may be included in the devices. The through-vias 125 may penetrate through the second region CR2 of the semiconductor chip 120c. In example embodiments, the through-vias 125 may further penetrate at least a portion of the first region CR1. The through-vias 125 may be electrically connected to the device layers 122 of the first region CR1 and may provide an electrical connection between the semiconductor chips 220a and the redistribution structure 110c. The through-vias 125 may be formed of a conductive material, and may include, for example, at least one of tungsten (W), aluminum (Al), and copper (Cu).

The semiconductor chips 220a may be stacked in the Z-direction on the semiconductor chip 120c. The semiconductor chips 220a may include through-vias 125 other than uppermost semiconductor chips. A first connection region BS1 may be formed between the semiconductor chip 120c and the semiconductor chips 220a, and second to fourth connection regions BS2, BS3, and BS4 may be between the semiconductor chips 220a. Although not specifically illustrated, at least a portion of the first to fourth connection regions BS1, BS2, BS3, and BS4 may have substantially the same structure as that of a connection region between the redistribution structure 110c and the semiconductor chip 120c. For example, each of the first to fourth connection regions BS1, BS2, BS3, and BS4 may include bumps arranged horizontally, may include pads above and below the bumps, and may include a non-conductive film layer surrounding the bumps.

In example embodiments, the UBM structures 140c, which may be formed in the same manner as the UBM structures 140a in FIGS. 1A and 1B and may have the same structure as that of the UBM structures 140a may also be used for the semiconductor package 100c having a three-dimensional integrated circuit structure.

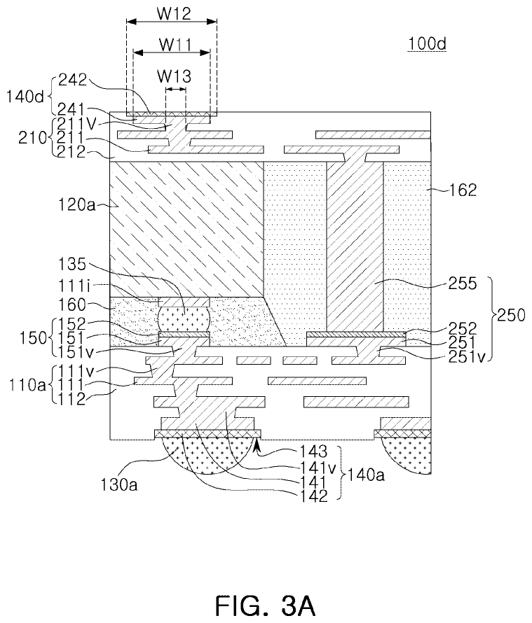

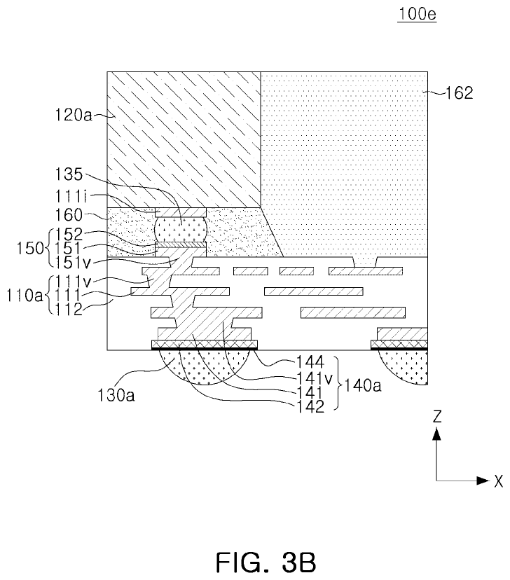

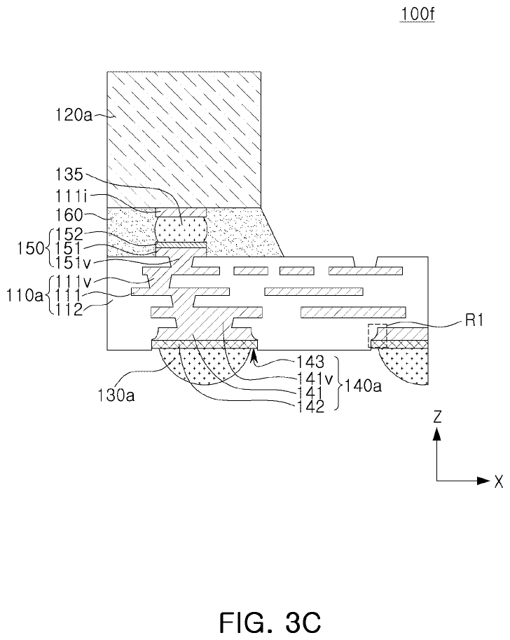

FIG. 3A is a cross-sectional diagram illustrating a structure in which a redistribution structure and UBM structures of a semiconductor package are above a semiconductor chip according to an example embodiment.

Referring to FIG. 3A, UBM structures 140d of a semiconductor package 100d in an example embodiment may be on an additional redistribution structure 210, and may be formed in the same manner as the UBM structures 140a in FIGS. 1A and 1B.

Accordingly, the maximum width W11 of the first UBM layer 241 included in the UBM structures 140d may be narrower than the maximum width W12 of the second UBM layer 242, and may be wider than the maximum width W13 of each of the additional vias 211V.

Here, the additional redistribution structure 210 may be regarded as being the same as the redistribution structure 110a in FIGS. 1A and 1B. The additional redistribution layer 211 of the additional redistribution structure 210 may be electrically connected to the semiconductor chip 120a through the conductive post 255 and the first and second connection structures 150 and 250.

FIG. 3B is a cross-sectional diagram illustrating a surface treatment layer of UBM structures of a semiconductor package according to an example embodiment.

Referring to FIG. 3B, each of the UBM structures 140a of the semiconductor package 100e in an example embodiment may further include a surface treatment layer 144 connected between one of the bumps 130a and the second UBM layer 142 and including a material (e.g., gold or an organic material) different from a second metal material (e.g., nickel). For example, the surface treatment layer 144 may include a metal material to supplement wettability of the second UBM layer 142 with respect to the bumps 130a, or may include an organic material to further improve reliability of the UBM structures 140a, or may not include the materials in example embodiments.

FIG. 3C is a cross-sectional diagram illustrating a detailed shape of a side surface of a first UBM layer of a semiconductor package according to an example embodiment.

Referring to FIG. 3C, the side surface R1 of the first UBM layer 141 of the semiconductor package 100f in an example embodiment may have a more curved tail shape or a gentler taper shape than that of the side surface of the second UBM layer 142. The phrase that the side surface has a more curved shape may indicate that the area or volume of the area virtually formed by the combination of a virtual straight line connecting the edge of the upper surface to the edge of the lower surface and the side surface may be greater. The phrase that the side surface has a gentler shape may indicate that the angle between the lower surface and the side surface may be smaller. Accordingly, the side surface R1 of the first UBM layer 141 may have a curvature or taper that is greater than a side surface of the second UBM layer.

For example, a more curved tail shape or a gentler taper shape of the side surface R1 of the first UBM layer 141 may be formed by wet-etching of the edge portion of the first UBM layer 141. Since the edge portion of the second UBM layer 142 may hardly be etched, the side surface of the second UBM layer 142 may have a shape relatively similar to a straight line or an angle formed with the lower surface may be almost perpendicular.

For example, when each of the first and second UBM layers 141 and 142 includes copper and nickel, an etching solution used for wet etching may be an etching solution reacting only with copper and nickel. Accordingly, the difference in horizontal size between the first and second UBM layers 141 and 142 may be implemented more efficiently.

The more curved tail shape or the gentler taper shape of the side surface R1 of the first UBM layer 141 may be advantageous to prevent substantial interaction between the edge portion of the first UBM layer 141 and the bumps 130a, and accordingly, the UBM structures 140a may properly maintain the shapes thereof when the bumps 130a are formed, and the UBM structures 140a may have improved reliability.

The degree of curvature of the curved tail shape of the side surface R1 of the first UBM layer 141 may be measured according to how continuously the slope of each z-coordinate of the side surface R1 changes. The degree of gentleness of the gentle taper shape of the side surface R1 of the UBM layer 141 may be measured according to how low the average value of the slope of each z-coordinate of the side surface R1 is. The slope may be measured by analysis using at least one of a micrometer, TEM, AFM, SEM, FIB, optical microscope, and surface profiler.

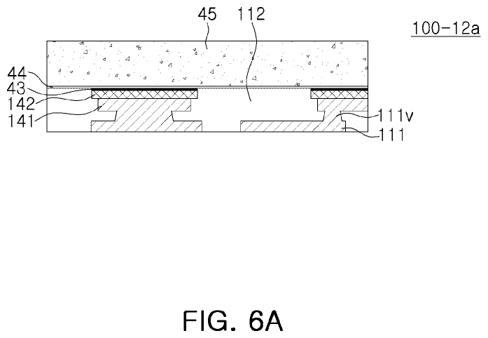

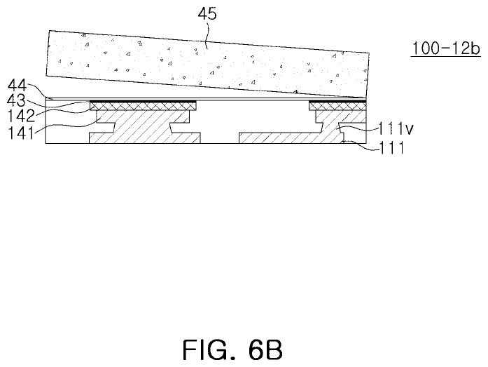

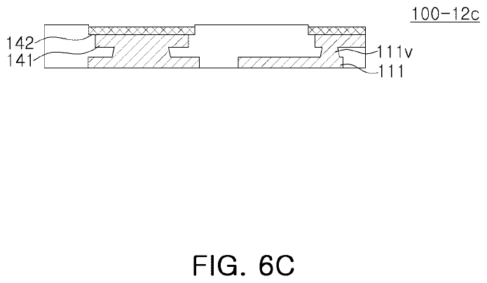

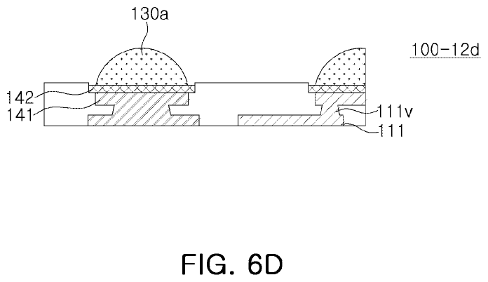

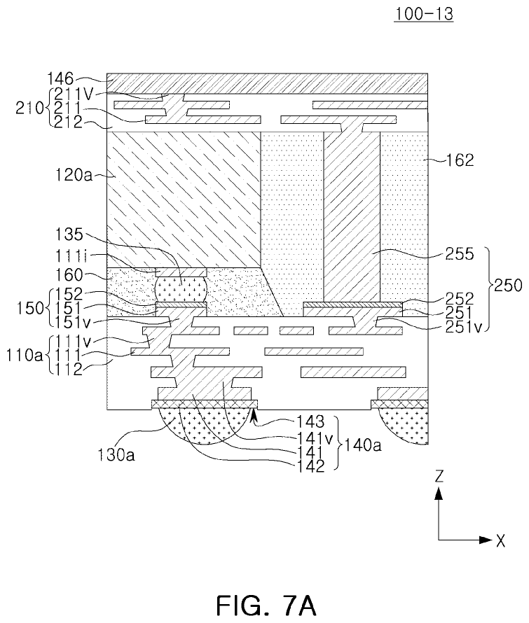

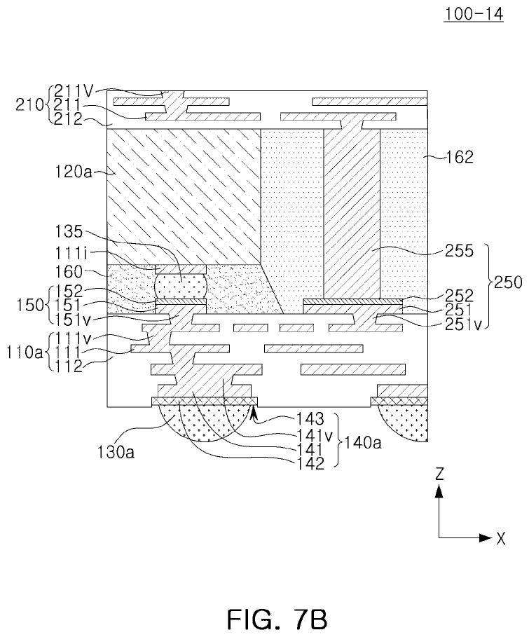

FIGS. 4A to 4E are cross-sectional diagrams illustrating a method of manufacturing which may implement a difference in area between surfaces of first and second UBM layers facing each other of a semiconductor package according to an example embodiment. FIGS. 5A to 5F are cross-sectional diagrams illustrating a method of forming a semiconductor chip of a semiconductor package and a surrounding structure thereof according to an example embodiment. FIGS. 6A to 6D are cross-sectional diagrams illustrating a method of arranging bumps of a semiconductor package on UBM structures according to an example embodiment. FIGS. 7A and 7B are cross-sectional diagrams illustrating an additional process of manufacturing a semiconductor package according to an example embodiment.

Referring to FIG. 4A, the first process 100-1 of a method of manufacturing a semiconductor package in an example embodiment may include preparing a carrier substrate 45 on which a seed layer 43p is on an upper surface thereof. For example, the adhesive layer 44 may be between the carrier substrate 45 and the seed layer 43p. The seed layer 43p may include a seed material (e.g., Ti or TiW) and may be formed by a sputtering process.

Referring to FIG. 4B, the second process 100-2 of the method of manufacturing the semiconductor package in an example embodiment may include forming a protective pattern 46 on a portion of the seed layer 43p. For example, the protective pattern 46 may include a material which may be used in an exposure and development method, such as PID.

Referring to FIG. 4C, the third process 100-3 of the method of manufacturing the semiconductor package in an example embodiment may include forming the UBM layer 142p including an nickel or an alloy of nickel on another portion of the seed layer 43p, and forming a first UBM layer 141p including copper or an alloy of copper on the second UBM layer 142p. For example, the second and first UBM layers 142p and 141p may be formed by an electroless plating process.

Referring to FIG. 4D, the fourth process 100-4 of a method of manufacturing a semiconductor package in an example embodiment may include removing a protective pattern. Accordingly, a portion of the seed layer 43p may be exposed.

Referring to FIG. 4E, the fifth process 100-5 of the method of manufacturing the semiconductor package in an example embodiment may include removing a portion of the seed layer 43 and an edge portion of the first UBM layer 141 together. For example, the etching solution used in the fifth process 100-5 may include a material which may hardly etch structures including nickel and selectively etching only structures including copper or titanium. Since the thickness of the seed layer 43 may be less than the thickness of the first UBM layer 141, the etching time of the fifth process 100-5 may match the time for etching the thin seed layer 43, such that the first UBM layer 141 may be formed without an additional protective pattern.

Also, since the edge portion of the first UBM layer 141 may also be etched, the horizontal size of the first UBM layer 141 may be smaller than the horizontal size of the second UBM layer 142, and the side surface of the first UBM layer 141 may have a more curved tail shape or a gentler taper shape than the shape of the side surface of the second UBM layer 142.

Referring to FIG. 5A, the sixth process 100-6 of the method of manufacturing the semiconductor package in an example embodiment may further include covering the first and second UBM layers 141 and 142 by forming the redistribution structure 110a in which at least one redistribution layer 111 and at least one insulating layer 112 are alternately stacked.

Referring to FIG. 5B, a seventh process 100-7 of the method of manufacturing the semiconductor package in an example embodiment may include forming a conductive post 255. For example, the conductive posts 255 may be formed by a plating process similar to the plating process of forming the first UBM layer 141p in FIG. 4C.

Referring to FIG. 5C, an eighth process 100-8 of a method of manufacturing a semiconductor package in an example embodiment may include disposing a semiconductor chip 120a on a redistribution structure 110a. Since the semiconductor chip 120a may be formed after the redistribution structure 110a is formed, the redistribution structure 110a may have a chip last RDL structure.

Referring to FIG. 5D, the ninth process 100-9 of the method of manufacturing the semiconductor package in an example embodiment may include forming an encapsulant 162 on the redistribution structure 110a.

Referring to FIG. 5E, a tenth process 100-10 of a method of manufacturing a semiconductor package in an example embodiment may include forming an additional redistribution structure 210 on a semiconductor chip 120a.

Referring to FIG. 5F, an eleventh process 100-11 of the method of manufacturing the semiconductor package in an example embodiment may include disposing an additional carrier substrate 146 on the additional redistribution structure 210.

The twelfth process 100-12 of the method of manufacturing the semiconductor package in an example embodiment may be performed according to the processes illustrated in FIGS. 6A to 6D. Referring to FIGS. 6A and 6B, portions 100-12a and 100-12b of the twelfth process of the method of manufacturing the semiconductor package in an example embodiment may include separating the carrier substrate 45 from the semiconductor package. Referring to FIGS. 6C and 6D, the other portions 100-12c and 100-12d of the twelfth process of the method of manufacturing the semiconductor package in an example embodiment may include removing the seed layer 43 and the adhesive layer 44 and forming bumps 130a.

Referring to FIGS. 7A and 7B, the thirteenth process 100-13 and 100-14 of the method of manufacturing the semiconductor package in an example embodiment may include separating the additional carrier substrate 146 from the semiconductor package. The semiconductor package in FIG. 1A may be formed by forming the additional UBM structure 241 on the upper surface of the additional redistribution structure 210. The semiconductor package 100a in FIG. 1A is not limited to the method of manufacturing the semiconductor package described with reference to FIGS. 4A to 7B.

According to the aforementioned example embodiments, reliability (or reliability for unit cost/size) of UBM structures may improve.

While the example embodiments have been illustrated and described above, it will be configured as apparent to those skilled in the art that modifications and variations could be made without departing from the scope of the present disclosure as defined by the appended claims.

What is claimed is:

1. A semiconductor package, comprising:
a redistribution structure in which at least one redistribution layer and at least one insulating layer are alternately stacked;
a semiconductor chip electrically connected to the at least one redistribution layer; and
bumps on the redistribution structure,
wherein the redistribution structure includes:
vias extending from the at least one redistribution layer in a vertical stacking direction of the redistribution structure; and
under bump metallurgy (UBM) structures electrically connected between the vias and the bumps and configured to face the bumps in the vertical stacking direction of the redistribution structure,
wherein each of the UBM structures includes:
a first UBM layer including a first metal material or an alloy of the first metal material; and
a second UBM layer between one of the bumps and the first UBM layer and including a second metal material different from the first metal material or an alloy of the second metal material, and
wherein an area of a surface of the second UBM layer facing the first UBM layer is greater than an area of a surface of the first UBM layer facing the second UBM layer.

2. The semiconductor package of claim 1,
wherein the first metal material is copper, and
wherein the second metal material is nickel.

3. The semiconductor package of claim 1,
wherein the first UBM layer contacts one of the vias, and
wherein a maximum width of the first UBM layer is wider than a maximum width of one of the vias.

4. The semiconductor package of claim 1, wherein the at least one redistribution layer comprises a plurality of redistribution layers, and a thickness of the first UBM layer is greater than a thickness of one of the plurality of redistribution layers and is greater than a thickness of the second UBM layer.

5. The semiconductor package of claim 1, wherein the second UBM layer includes a surface that does overlap the first UBM layer in a vertical direction and extends around a perimeter of the first UBM layer and completely surrounds a region in which the second UBM layer overlaps the first UBM layer in the vertical direction.

6. The semiconductor package of claim 1, wherein the redistribution structure is between the semiconductor chip and the bumps.

7. The semiconductor package of claim 6, further comprising:
an encapsulant encapsulating the semiconductor chip; and
a conductive post extending through the encapsulant and electrically connected to the at least one redistribution layer.

8. The semiconductor package of claim 1, wherein each of the UBM structures further includes a surface treatment layer between one of the bumps and the second UBM layer and including a material different from the second metal material.

9. The semiconductor package of claim 1,
wherein the at least one insulating layer comprises a plurality of insulating layers, and at least one of the plurality of insulating layers is on a side surface of the UBM structures, and
wherein a surface of the second UBM layer facing one of the bumps is on a level between an upper surface and a lower surface of the one of the plurality of insulating layers on the side surface of the UBM structures.

10. The semiconductor package of claim 1, wherein the at least one insulating layer is in contact with a portion of a surface of the second UBM layer facing the first UBM layer and is in contact with a side surface of the second UBM layer.

11. The semiconductor package of claim 1, wherein a side surface of the first UBM layer has a curvature that is greater than a side surface of the second UBM layer.

12. A semiconductor package, comprising:
a redistribution structure in which at least one redistribution layer and at least one insulating layer are alternately stacked;
a semiconductor chip electrically connected to the at least one redistribution layer; and
bumps on the redistribution structure,
wherein the redistribution structure includes:
vias extending from the at least one redistribution layer in a vertical stacking direction of the redistribution structure; and
under bump metallurgy (UBM) structures electrically connected between the vias and the bumps and configured to face the bumps in the vertical stacking direction of the redistribution structure,
wherein each of the UBM structures includes:
a first UBM layer including a first metal material or an alloy of the first metal material; and
a second UBM layer between one of the bumps and the first UBM layer and including a second metal material different from the first metal material or an alloy of the second metal material, and
wherein a side surface of the first UBM layer has a curvature or taper that is greater than a side surface of the second UBM layer.

13. The semiconductor package of claim 12,
wherein the first metal material is copper, and
wherein the second metal material is nickel.

14. The semiconductor package of claim 13,
wherein the at least one insulating layer comprises a plurality of insulating layers, and one of the plurality of insulating layers is on a side surface of the UBM structures, and
wherein a surface of the second UBM layer facing one of the bumps is on a level between an upper surface and a lower surface of the one of the plurality of insulating layers on the side surface of the UBM structures.

15. The semiconductor package of claim 14,
wherein the redistribution structure is between the semiconductor chip and the bumps,
wherein the first UBM layer is in contact with one of the vias, and
wherein a maximum width of the first UBM layer is wider than a maximum width of one of the vias.

16. The semiconductor package of claim 15,
wherein the at least one redistribution layer comprises a plurality of redistribution layers, and a thickness of the first UBM layer is greater than a thickness of one of the plurality of redistribution layers and is greater than a thickness of the second UBM layer,
wherein a total thickness of the first and second UBM layers is 5 μm or more and 20 μm or less,
wherein a maximum width of a surface of the second UBM layer facing the first UBM layer is greater than 50 μm and less than or equal to 300 μm, and
wherein a maximum width of the surface of the first UBM layer facing the second UBM layer is 50 μm or more and less than 300 μm.

17. The semiconductor package of claim 16,
wherein an area of a surface of the second UBM layer facing the first UBM layer is larger than an area of a surface of the first UBM layer facing the second UBM layer, and
wherein the at least one insulating layer is in contact with a portion of a surface of the second UBM layer facing the first UBM layer and is in contact with a side surface of the second UBM layer.

18. A semiconductor package, comprising:
a redistribution structure in which at least one redistribution layer and at least one insulating layer are alternately stacked;
a semiconductor chip electrically connected to the at least one redistribution layer; and
bumps on the redistribution structure,
wherein the redistribution structure includes:
vias extending from the at least one redistribution layer in a vertical stacking direction of the redistribution structure; and
under bump metallurgy (UBM) structures electrically connected between the vias and the bumps and configured to face the bumps in the vertical stacking direction of the redistribution structure,
wherein each of the UBM structures includes:
a second UBM layer embedded in the at least one insulating layer and including a second metal material or an alloy of the second metal material; and
a first UBM layer electrically connected between one of the vias and the second UBM layer and including a first metal material different from the second metal material or an alloy of the first metal material, and
wherein the at least one insulating layer is in contact with a portion of a surface of the second UBM layer facing the first UBM layer and is in contact with a side surface of the second UBM layer.

19. The semiconductor package of claim 18,
wherein the first metal material is copper,
wherein the second metal material is nickel,
wherein the at least one insulating layer comprises a plurality of insulating layers, and
one of the plurality of insulating layers is on a side surface of the UBM structures,
wherein a surface of the second UBM layer facing one of the bumps is on a level between an upper surface and a lower surface of the one of the plurality of insulating layers on the side surface of the UBM structures.

20. The semiconductor package of claim 18,
wherein the redistribution structure is between the semiconductor chip and the bumps,
wherein the first UBM layer is in contact with one of the vias,
wherein a maximum width of the first UBM layer is wider than a maximum width of one of the vias, and
wherein a side surface of the first UBM layer has a curvature or taper that is greater than a side surface of the second UBM layer.
